(19) United States
(12) Patent Application Publication
(10) Pub. No.: US 2005/0212130 A1
(43) Pub. Date: Sep. 29, 2005

(54) Semiconductor chip, semiconductor device, method for producing semiconductor device, and electronic equipment

(76) Inventor: Hideo Imai, Suwa (JP)

Correspondence Address: HARNESS, DICKEY & PIERCE, P.L.C., P.O. BOX 828, BLOOMFIELD HILLS, MI, 48303, US

(21) Appl. No.: 11/064,596

(22) Filed: Feb. 24, 2005

(30) Foreign Application Priority Data
Mar. 26, 2004 (JP) 2004-091171
Nov. 2, 2004 (JP) 2004-319480

(51) Int. Cl. H01L 23/48; H01L 21/60

(52) U.S. Cl. 257/737; 438/614; 438/615; 257/750

(57) ABSTRACT

A semiconductor device includes a semiconductor chip having a bump and a wiring substrate having a land, wherein the bump and the land are connected through conductive particles dispersed in an insulating material. The bump includes a first conductive layer, a second conductive layer that is in contact with the first conductive layer, and a third conductive layer that is in contact with the second conductive layer. The conductive particles are inserted in the third conductive layer to establish the electrical connection.

### CROSS-REFERENCE OF RELATED APPLICATIONS

The entire disclosures of Japanese Patent Application Nos. 2004-091171 filed on Mar. 26, 2004 and 2004-319480 filed Nov. 2, 2004 are hereby incorporated by reference.

### BACKGROUND OF THE INVENTION

1. Field of the Invention

The present invention relates to a semiconductor chip, a semiconductor device, a method for producing the semiconductor device, and electronic equipment, and in particular, to a semiconductor chip suitable for a face-down mounting, which is also referred to as flip-chip mounting.

2. Description of the Related Art

Recently, as the size of electronic equipment such as cellular phones and notebook-size computers has been decreasing, the downsizing and the high integration of semiconductor devices have been desired. As a result, a face-down mounting, which is also referred to as flip-chip mounting, has been developed as a method for mounting semiconductor chips. Since the face-down mounting allows the integration to be performed with high density, this method is used in various types of portable electronic equipment.

In a known method for connecting a semiconductor device using a flip-chip mounting, a bump composed of nickel and gold is formed on a semiconductor chip. The bump on the semiconductor chip is electrically connected with an electrode terminal on a printed wiring board through an anisotropic conductive resin (see, for example, Japanese Unexamined Patent Application Publication No. 2000-286299, FIG. 1).

In the above known method for connecting a semiconductor device using the flip-chip mounting, conductive particles in the anisotropic conductive resin layer are inserted in the gold layer that covers the surface of the bump on the semiconductor chip. In order to insert the conductive particles in the gold layer sufficiently, the thickness of the gold layer must be increased, thereby increasing the cost. In addition, the inside of the bump on the semiconductor chip is composed of nickel, which has a high hardness. Accordingly, when the gold layer has a small thickness, the conductive particles cannot be inserted in the bump sufficiently. As a result, the connection reliability is decreased.

### SUMMARY OF THE INVENTION

Accordingly, it is an object of the present invention to provide a semiconductor chip that can be produced with a low cost and has high connection reliability, a semiconductor device including the semiconductor chip, a method for producing the semiconductor device, and electronic equipment including the semiconductor device.

A semiconductor device according to the present invention includes a semiconductor chip including a bump, a wiring substrate including a land, and conductive particles for connecting the bump with the land, the conductive particles being dispersed in an insulating material. In the semiconductor device, the bump includes a first conductive layer, a second conductive layer that is in contact with the first conductive layer, and a third conductive layer that is in contact with the second conductive layer, and the conductive particles are inserted in the third conductive layer to establish the electrical connection.

Since the conductive particles are inserted in the third conductive layer to establish the electrical connection, the conductive particles can be disposed between the bump of the semiconductor chip and the land of the wiring substrate to maintain a stable contact state. As a result, a semiconductor device having an excellent reliability in electrical connection can be inexpensively provided.

According to the semiconductor device of the present invention, the thickness of the third conductive layer is preferably controlled such that at least a quarter of the diameter of the conductive particles is inserted in the third conductive layer.

In general, the surface of the bump of the semiconductor chip and the surface of the land of the wiring substrate are not flat but have minute irregularities. If the amount of the insertion of the conductive particles in the third conductive layer is less than a quarter of the diameter, the contact area becomes insufficient depending on the irregularity distributions. In such a case, sufficient electrical connection cannot be achieved. On the other hand, when at least a quarter of the diameter of the conductive particles is inserted in the third conductive layer, the effect of the irregularities can be absorbed. Accordingly, an excellent electrical connection can be provided between the bump of the semiconductor chip and the land of the wiring substrate to improve the connection reliability.

According to the semiconductor device of the present invention, the thickness of the third conductive layer is preferably controlled such that at least a half of the diameter of the conductive particles is inserted in the third conductive layer and the bump is directly in contact with the land.

The thickness of the third conductive layer is preferably controlled such that at least a half of the diameter of the conductive particles is inserted in the third conductive layer and the bump is directly in contact with the land. As a result, the conductive particles are reliably disposed between the third conductive layer and the land of the wiring substrate to maintain the contact state. This structure provides an excellent electrical connection to improve the reliability.

Preferably, the semiconductor device according to the present invention further includes a catalyst disposed between the first conductive layer and the second conductive layer and/or between the second conductive layer and the third conductive layer.

When the first conductive layer is directly brought into contact with the second conductive layer, or when the second conductive layer is directly brought into contact with the third conductive layer, the adhesiveness is not sufficient in some combinations of the material (for example, nickel and copper, or copper and tin). In such a case, a problem, for example, the peeling of the second conductive layer or the third conductive layer occurs. However, when the catalyst is disposed between the first conductive layer and the second conductive layer and/or between the second conductive layer and the third conductive layer, the adhesiveness between the first conductive layer and the second conductive layer and/or between the second conductive layer and the third conductive layer can be improved by appropriately selecting the material of the catalyst.

Preferably, the semiconductor device according to the present invention further includes a passivation film having an opening on an external connection electrode, wherein the first conductive layer is disposed in the opening so as not to be in contact with the surface of the passivation film except for the side faces of the opening.

If the first conductive layer composed of a hard material is also disposed on the surface of the passivation film, the stress caused by pressurizing to mount the semiconductor chip on the wiring substrate is concentrated on the passivation film to generate cracks. However, when the first conductive layer is disposed so as not to be in contact with the surface of the passivation film except for the side faces of the opening, only the second conductive layer and the third conductive layer are disposed on the passivation film. Accordingly, when the semiconductor chip is mounted by pressurizing, the stress applied on the passivation film can be relieved by the flexibility of the second conductive layer and the third conductive layer. As a result, the generation of damage such as cracks on the passivation film can be prevented. Thus, a semiconductor chip having high connection reliability can be achieved.

According to the semiconductor device of the present invention, the conductive particles preferably have a hardness higher than the hardness of the third conductive layer.

Since the conductive particles have a hardness higher than the hardness of the third conductive layer, the conductive particles are reliably inserted in the third conductive layer. As a result, the reliability of the electrical connection can be improved.

According to the semiconductor device of the present invention, the conductive particles preferably include nickel.

Because of the relatively high hardness of nickel, the conductive particles can be reliably inserted in the third conductive layer composed of, for example, tin. As a result, the reliability of the electrical connection can be improved. In addition, when the conductive particles composed of nickel having a high hardness are used, the conductive particles can be inserted in the land of the wiring substrate. Accordingly, the connection reliability of the semiconductor device can be further improved.

According to the semiconductor device of the present invention, a part of the first conductive layer adjacent to the second conductive layer preferably forms an auxiliary conductive layer, and the auxiliary conductive layer preferably has a hardness lower than the hardness of the remaining part of the first conductive layer other than the auxiliary conductive layer.

A part of the first conductive layer adjacent to the second conductive layer preferably forms the auxiliary conductive layer composed of a material having a low hardness. This structure can effectively prevent the generation of cracks on a silicon portion of the semiconductor chip.

According to the semiconductor device of the present invention, the auxiliary conductive layer is preferably composed of gold.

Since gold has a low hardness, the generation of cracks on a silicon portion of the semiconductor chip can be effectively prevented.

A semiconductor chip according to the present invention includes a substrate; an external connection electrode disposed on the substrate; a bump including a first conductive layer, a second conductive layer disposed on the first conductive layer, and a third conductive layer disposed on the second conductive layer, the bump being electrically connected with the external connection electrode; and a passivation film having an opening on the external connection electrode. In the semiconductor chip, the first conductive layer is in contact with the upper surface of the external connection electrode in the inner surface of the opening of the passivation film and is not in contact with the surface of the passivation film except for the side faces of the opening.

If the first conductive layer composed of a hard material is also disposed on the surface of the passivation film, the stress caused by pressurizing to mount the semiconductor chip on the wiring substrate is concentrated on the passivation film to generate cracks. However, when the first conductive layer is disposed so as not to be in contact with the surface of the passivation film except for the side faces of the opening, only the second conductive layer and the third conductive layer are disposed on the passivation film. Accordingly, when the semiconductor chip is mounted by pressurizing, the stress applied on the passivation film can be relieved by the flexibility of the second conductive layer and the third conductive layer. As a result, the generation of damage such as cracks on the passivation film can be prevented. Thus, a semiconductor chip having high connection reliability can be achieved.

According to the semiconductor chip of the present invention, the third conductive layer is preferably composed of tin.

Since tin has a low hardness, the conductive particles can be sufficiently inserted in the third conductive layer. Therefore, a semiconductor chip having high connection reliability can be inexpensively provided.

According to the semiconductor chip of the present invention, the second conductive layer is preferably composed of copper.

Since the second conductive layer is composed of copper, the third conductive layer composed of tin can be formed by electroless plating. Therefore, a semiconductor chip having high connection reliability can be inexpensively provided.

According to the semiconductor chip of the present invention, the external connection electrode preferably has a thickness of at least 0.2 μm.

The external connection electrode composed of a metal such as aluminum preferably has a thickness of at least 0.2 μm. As a result, for example, when the semiconductor chip is bonded on the wiring substrate, the generation of cracks on a silicon portion (substrate) of the semiconductor chip can be prevented.

According to the semiconductor chip of the present invention, a part of the first conductive layer adjacent to the second conductive layer preferably forms an auxiliary conductive layer, and the auxiliary conductive layer preferably has a hardness lower than the hardness of the remaining part of the first conductive layer other than the auxiliary conductive layer.

A part of the first conductive layer adjacent to the second conductive layer preferably forms the auxiliary conductive layer composed of a material having a low hardness. This structure can more effectively prevent the generation of cracks on a silicon portion of the semiconductor chip.

According to the semiconductor chip of the present invention, the auxiliary conductive layer is preferably composed of gold.

Since gold has a low hardness, the generation of cracks on a silicon portion of the semiconductor chip can be effectively prevented.

According to the present invention, in a method for producing a semiconductor device to connect a semiconductor chip including a bump with a wiring substrate including a land, the method includes the steps of forming a first conductive layer of the bump, forming a second conductive layer of the bump so as to be in contact with the first conductive layer, forming a third conductive layer of the bump so as to be in contact with the second conductive layer, disposing an insulating material in which conductive particles are dispersed on the wiring substrate or the semiconductor chip, pressing the bump or the land toward the insulating material to insert the conductive particles in the third conductive layer, thereby electrically connecting the bump with the land.

In the semiconductor device produced by the above method, conductive particles are disposed between the bump and the land of the wiring substrate to maintain a stable electrical contact state. As a result, a semiconductor device having an excellent reliability in electrical connection can be inexpensively provided by a simple method.

According to the present invention, preferably, the method for producing a semiconductor device further includes the step of providing a catalyst between the first conductive layer and the second conductive layer and/or between the second conductive layer and the third conductive layer.

The adhesiveness between the first conductive layer and the second conductive layer and/or between the second conductive layer and the third conductive layer can be improved by appropriately selecting the material of the catalyst.

According to the method for producing a semiconductor device of the present invention, at least one of the first conductive layer, the second conductive layer, and the third conductive layer is preferably formed by electroless plating.

The use of electroless plating can form stable bumps having a small variation of their height. This method can provide an inexpensive semiconductor device having high reliability.

According to the present invention, preferably, the method for producing a semiconductor device further includes the step of forming an auxiliary conductive layer as a part of the first conductive layer adjacent to the second conductive layer, wherein the auxiliary conductive layer has a hardness lower than the hardness of the remaining part of the first conductive layer other than the auxiliary conductive layer.

A part of the first conductive layer adjacent to the second conductive layer is preferably formed as the auxiliary conductive layer composed of a material having a low hardness. This structure can effectively prevent the generation of cracks on a silicon portion of the semiconductor chip.

Electronic equipment according to the present invention includes any one of the above semiconductor devices.

Since the electronic equipment includes the above semiconductor device having high connection reliability, inexpensive electronic equipment having high reliability can be achieved.

### BRIEF DESCRIPTION OF THE DRAWINGS

FIG. 1 is a schematic cross-sectional view showing a semiconductor device according to a first embodiment of the present invention;

FIG. 2 is a schematic cross-sectional view showing the state before mounting a semiconductor chip on a wiring substrate in the semiconductor device in FIG. 1;

FIGS. 3A to 3D are schematic cross-sectional views showing the steps of producing the semiconductor device according to the first embodiment of the present invention;

FIGS. 4E to 4G are schematic cross-sectional views showing the subsequent steps of FIGS. 3A to 3D;

FIG. 5 is a schematic cross-sectional view showing the state before mounting a semiconductor chip on a wiring substrate in a semiconductor device according to a second embodiment of the present invention;

FIG. 6 is a schematic cross-sectional view showing the state before mounting a semiconductor chip on a wiring substrate in a semiconductor device according to a third embodiment of the present invention; and

FIG. 7 is a schematic perspective view showing an example of electronic equipment according to a fourth embodiment of the present invention.

### DESCRIPTION OF THE PREFERRED EMBODIMENTS

### First Embodiment

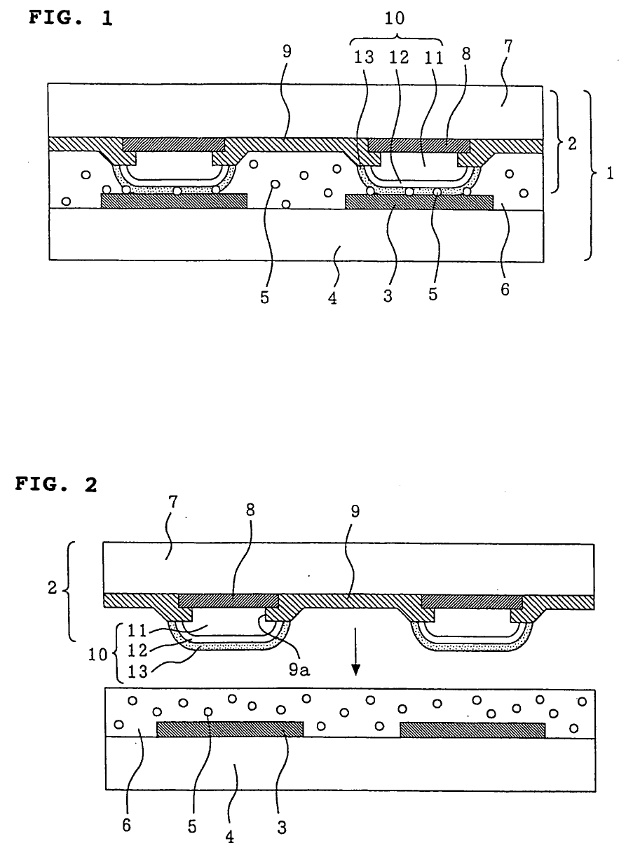

FIG. 1 is a schematic cross-sectional view showing a semiconductor device according to a first embodiment of the present invention. FIG. 1 shows a part of the semiconductor device.

A semiconductor device 1 according to the first embodiment includes a semiconductor chip 2, a wiring substrate 4 having at least one land 3, and an anisotropic conductive resin layer 6 in which conductive particles 5 are dispersed. The semiconductor chip 2 includes a substrate 7, at least one external connection electrode 8, a passivation film 9, and a bump 10. The bump 10 includes a first conductive layer 11, a second conductive layer 12, and a third conductive layer 13. The semiconductor device 1 may include components other than the components shown in FIG. 1.

FIG. 2 is a schematic cross-sectional view showing the state before mounting the semiconductor chip 2 on the wiring substrate 4 in the semiconductor device 1 in FIG. 1. A method for mounting the semiconductor chip 2 on the wiring substrate 4 will be described later.

In the semiconductor chip 2, for example, the at least one external connection electrode 8 is disposed on one surface of the substrate 7 having an integrated circuit (not shown in the figure) thereon and composed of silicon. A bump 10 is disposed so as to be in contact with the external connection electrode 8. The bump 10 includes the first conductive layer 11, the second conductive layer 12, and the third conductive layer 13. The first conductive layer 11 is composed of, for example, nickel and has a thickness of about 10 μm. The second conductive layer 12 is composed of, for example, copper and has a thickness of about 5 μm. The third conductive layer 13 is composed of, for example, tin and has a thickness of about 5 μm. In this first embodiment, the first conductive layer 11 is composed of nickel, the second conductive layer 12 is composed of copper, and the third conductive layer 13 is composed of tin. The external connection electrode 8 is composed of, for example, aluminum or copper and is electrically connected with the integrated circuit formed on the substrate 7.

The passivation film 9 composed of, for example, silicon oxide is disposed on the surface of the substrate 7, the surface having the external connection electrode 8 thereon. An opening 9a is formed in the passivation film 9 so as to expose a part of the external connection electrode 8. The passivation film 9 covers the edge of the external connection electrode 8. In general, the opening 9a is formed such that the central part of the external connection electrode 8 is opened. Thus, the passivation film 9 is disposed on the area except for the opening 9a on the surface of the substrate 7, the surface having the external connection electrode 8 thereon.

The first conductive layer 11 covers the opening 9a and is in contact with the external connection electrode 8. The second conductive layer 12 covers the first conductive layer 11 and is in contact with the first conductive layer 11. The third conductive layer 13 covers the second conductive layer 12 and is in contact with the second conductive layer 12. The second conductive layer 12 or the third conductive layer 13 need not cover the entire part of the first conductive layer 11 or the second conductive layer 12.

A catalyst (not shown in the figure) composed of, for example, palladium is applied between the first conductive layer 11 and second conductive layer 12 and/or between the second conductive layer 12 and the third conductive layer 13. The catalyst increases the adhesiveness between the first conductive layer 11 composed of nickel and the second conductive layer 12 composed of copper and/or between the second conductive layer 12 composed of copper and the third conductive layer 13 composed of tin. Accordingly, the connection reliability can be improved.

The wiring substrate 4 is, for example, a polyethylene terephthalate (PET) substrate. The at least one land 3 disposed on one surface of the wiring substrate 4 is composed of a metal such as silver or copper. The wiring substrate 4 may be a flexible substrate such as a polyimide resin film and a polyester film; or a rigid substrate such as a glass epoxy substrate and a ceramic substrate. The land 3 may be composed of a metal other than silver and copper.

The component of the anisotropic conductive resin layer 6 other than the conductive particles 5 is composed of an insulating material such as a thermosetting epoxy resin. The anisotropic conductive resin layer 6 is disposed between the face having the bump 10 of the semiconductor chip 2 thereon and the face having the land 3 of the wiring substrate 4 thereon. Thus, the anisotropic conductive resin layer 6 seals to bond between the semiconductor chip 2 and the wiring substrate 4.

The conductive particles 5 are composed of a material, for example, nickel, which is harder than the third conductive layer 13. The conductive particles 5 have a diameter of about 0.2 to about 5 μm, generally about 4 μm. The conductive particles 5 may include at least nickel. For example, the conductive particles 5 may be composed of a resin coated with nickel and gold. Other metals may also be used.

According to the first embodiment shown in FIG. 1, the semiconductor device 1 is formed by mounting the semiconductor chip 2 on the wiring substrate 4. In this state, the outermost third conductive layer 13 of the bump 10 is in contact with the land 3. The conductive particles 5 disposed on the area where the third conductive layer 13 and the land 3 are in contact with are inserted in the third conductive layer 13. This is because the conductive particles 5 composed of, for example, nickel having a high hardness are readily inserted into the third conductive layer 13 composed of tin having a low hardness. In addition, the conductive particles 5 can break an oxide film (not shown in figure) on the surface of the land 3 composed of, for example, silver or copper to improve the connection reliability.

Preferably, at least a quarter of the diameter of the conductive particles 5 is inserted in the third conductive layer 13. The surface of the bump of the semiconductor chip and the surface of the land of the wiring substrate are not flat but have minute irregularities. If the amount of the insertion of the conductive particles in the third conductive layer is less than a quarter of the diameter, the contact area becomes insufficient depending on the irregularity distributions. In such a case, sufficient electrical connection cannot be achieved. As in this first embodiment, when the third conductive layer 13 is in contact with the land 3, at least a half of the diameter of the conductive particles 5 can be inserted in the third conductive layer 13. As a result, the conductive particles 5 are reliably disposed between the third conductive layer 13 and the land 3 on the wiring substrate 4 to maintain the electrical contact state. Accordingly, a reliable electrical connection can be provided. Thus, the bump 10 is electrically connected with the land 3 through the conductive particles 5.

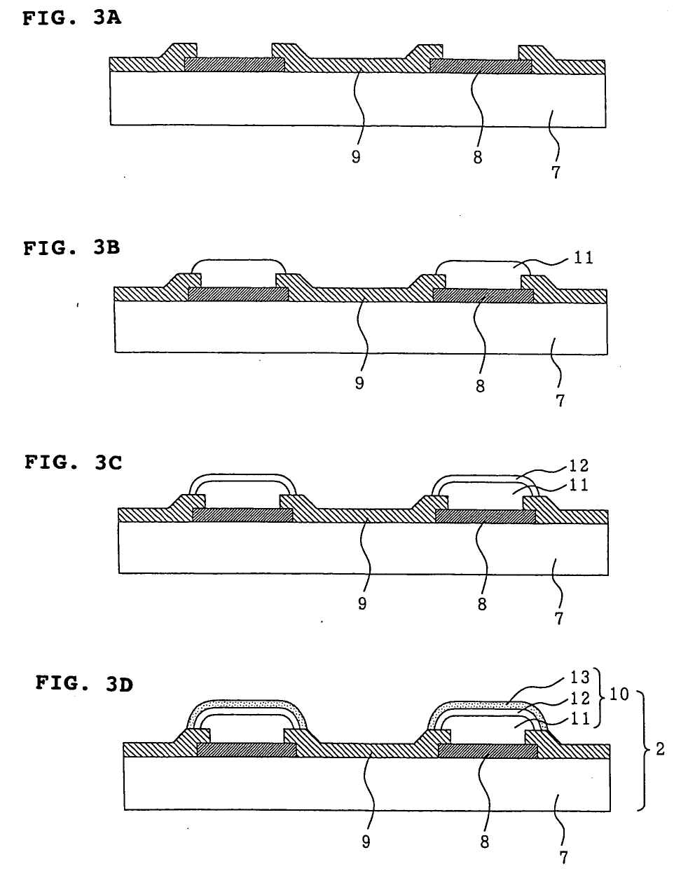

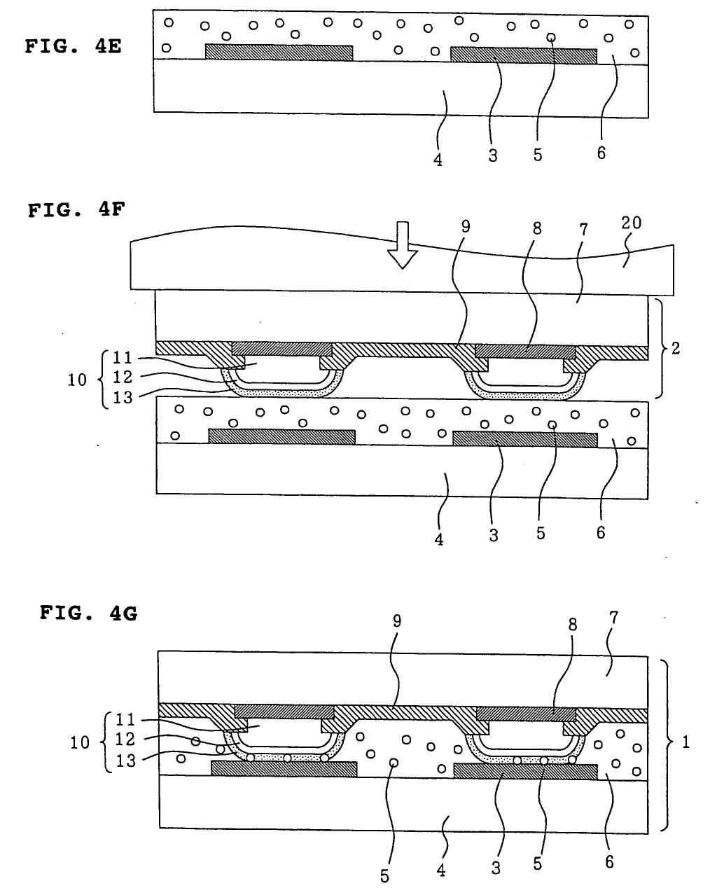

FIGS. 3A to 3D and FIGS. 4E to 4G are schematic cross-sectional views showing the steps of producing the semiconductor device according to the first embodiment of the present invention. FIGS. 3A to 3D and FIGS. 4E to 4G show the steps of mounting the semiconductor chip 2 shown in FIG. 2 on the wiring substrate 4 to produce the semiconductor device 1 shown in FIG. 1.

Firstly, a substrate 7 having an integrated circuit (not shown in the figure) thereon and composed of, for example, silicon is prepared. At least one external connection electrode 8 is formed on one surface of the substrate 7 in advance. The external connection electrode 8 is composed of, for example, aluminum or copper and is electrically connected with the integrated circuit formed on the substrate 7.

Subsequently, a passivation film 9 is formed on the surface having the external connection electrode 8 of the substrate 7 (FIG. 3A). The passivation film 9 is composed of silicon oxide, silicon nitride, a polyimide resin, or the like. As described above, the passivation film 9 includes an opening so as to expose a part of the external connection electrode 8. The passivation film 9 covers the edge of the external connection electrode 8.

A first conductive layer 11 composed of, for example, nickel is formed by electroless plating such that the first conductive layer 11 is in contact with the external connection electrode 8 and covers the opening (FIG. 3B). When the external connection electrode 8 is composed of aluminum, a zincate process is performed on the surface of the external connection electrode 8 before the first conductive layer 11 is formed. The aluminum is substituted with zinc by precipitation to form a metal film (not shown in the figure) composed of zinc. The first conductive layer 11 is formed by electroless plating as follows. The zincate-processed external connection electrode 8 is immersed in an electroless nickel plating solution to utilize a reaction for substituting the zinc metal film with nickel. For example, the first conductive layer 11 is formed so as to have a thickness of about 10 μm. In the first embodiment, a mushroom-shaped bump 10 (including the first conductive layer 11, a second conductive layer 12, and a third conductive layer 13) is formed without using a mask such as a resist. Alternatively, a straight wall-shaped bump 10 may be formed using a mask such as a resist.

A catalyst (not shown in the figure) is then applied on the surface of the first conductive layer 11. Examples of the catalyst include palladium. The catalyst can be applied by a sensitizing-activation method or a catalyst-accelerator method.

Subsequently, a second conductive layer 12 composed of copper is formed by electroless plating such that the second conductive layer 12 covers the first conductive layer 11 and is in contact with the first conductive layer 11 (FIG. 3C). In order to form the second conductive layer 12, the first conductive layer 11 is immersed in a copper plating solution to precipitate copper using the palladium applied on the surface of the first conductive layer 11 as a catalyst. Such an application of the catalyst can increase the adhesiveness between the first conductive layer 11 and the second conductive layer 12. For example, the second conductive layer 12 is formed so as to have a thickness of about 5 μm.

Subsequently, a third conductive layer 13 composed of tin is formed by electroless plating such that the third conductive layer 13 covers the second conductive layer 12 and is in contact with the second conductive layer 12 (FIG. 3D) Since the second conductive layer 12 is composed of copper, the third conductive layer 13 can also be formed by electroless plating as in the first conductive layer 11 and the second conductive layer 12. In order to increase the adhesiveness between the second conductive layer 12 and the third conductive layer 13, a catalyst may be applied on the surface of the second conductive layer 12 in advance.

Thus, the bump 10 including the first conductive layer 11, the second conductive layer 12, and the third conductive layer 13 is formed on the external connection electrode 8 by the above steps shown in FIGS. 3A to 3D to complete the semiconductor chip 2.

In addition to the semiconductor chip 2, a wiring substrate 4 having at least one land 3 thereon is prepared. An anisotropic conductive resin layer 6 is formed on the surface of the wiring substrate 4 on which the at least one land 3 is formed (FIG. 4E). The wiring substrate 4 may be a PET substrate; a flexible substrate such as a polyimide resin film and a polyester film; or a rigid substrate such as a glass epoxy substrate and a ceramic substrate. The land 3 is composed of a metal, for example, silver or copper. As described above, conductive particles 5 are dispersed in the anisotropic conductive resin layer 6.

The component of the anisotropic conductive resin layer 6 other than the conductive particles 5 is composed of an insulating material such as a thermosetting epoxy resin. The anisotropic conductive resin layer 6 can be formed on the surface having the land 3 of the wiring substrate 4 by a screen printing method or a dispensing method. The conductive particles 5 dispersed in the anisotropic conductive resin layer 6 have a diameter of about 0.2 to about 5 μm and are composed of, for example, nickel or a resin coated with nickel and gold. Alternatively, a film in which the conductive particles 5 are dispersed may be applied on the surface of the wiring substrate 4 to form the anisotropic conductive resin layer 6.

Subsequently, the face having the bump 10 of the semiconductor chip 2, which is shown in FIG. 3D, and the face having the anisotropic conductive resin layer 6 of the wiring substrate 4 are allowed to face each other. The semiconductor chip 2 and the wiring substrate 4 are positioned such that the bump 10 and the land 3 are matched in position. Herein, the bump 10 (external connection electrode 8) formed on the semiconductor chip 2 and the land 3 formed on the wiring substrate 4 are formed in advance such that the position of the bump 10 and the position of the land 3 are matched when they are positioned.

Subsequently, a thermocompression bonding device 20 having a flat surface is heated at about the curing temperature of the anisotropic conductive resin layer 6. The flat surface of the thermocompression bonding device 20 is brought into contact with a surface of the semiconductor chip 2 opposite to the surface having the bump 10. The bump 10 is then pressed toward the anisotropic conductive resin layer 6 (FIG. 4F).

In the first embodiment, the anisotropic conductive resin layer 6 is formed on the wiring substrate 4 and the bump 10 is pressed toward the anisotropic conductive resin layer 6. Alternatively, the anisotropic conductive resin layer 6 may be formed on the semiconductor chip 2 and the land 3 may be pressed toward the anisotropic conductive resin layer 6.

As shown in FIG. 4F, when the bump 10 is pressed toward the anisotropic conductive resin layer 6 with the thermocompression bonding device 20, the bump 10 pushes away the anisotropic conductive resin layer 6 disposed on the surface of the wiring substrate 4 to be in contact with the land 3. As a result, conductive particles 5 dispersed in the anisotropic conductive resin layer 6 are sandwiched between the outermost third conductive layer 13 of the bump 10 and the land 3. Since the conductive particles 5 are composed of, for example, nickel, which is harder than the third conductive layer 13, the conductive particles 5 are inserted in the third conductive layer 13. As described above, at least a quarter of the diameter of the conductive particles 5 is inserted in the third conductive layer 13. When the third conductive layer 13 is in contact with the land 3, at least a half of the diameter of the conductive particles 5 can be inserted in the third conductive layer 13. As a result, the conductive particles 5 are reliably disposed between the third conductive layer 13 and the land 3 on the wiring substrate 4 to provide a reliable electrical connection. Furthermore, it is advantageous that this device is less susceptible to, for example, expansion and contraction of the insulating material caused by vibration or temperature change.

Subsequently, the anisotropic conductive resin layer 6 is cured by heating with the thermocompression bonding device 20 to seal and bond between the semiconductor chip 2 and the wiring substrate 4. Thus, the semiconductor device 1 is completed (FIG. 4G).

In the step of pressing the bump 10 toward the anisotropic conductive resin layer 6, which is shown in FIG. 4F of the first embodiment, small vibration by, for example, ultrasonic waves may be added. The addition of such small vibration by, for example, ultrasonic waves readily breaks oxide films on the surfaces of the third conductive layer 13 composed of tin and the land 3. As a result, the connection reliability can be improved.

In the first embodiment, the third conductive layer 13 is formed such that the conductive particles 5 are inserted in the third conductive layer 13 to provide the electrical connection. In such a case, the conductive particles 5 are not simply in contact with the third conductive layer 13 but inserted in the third conductive layer 13 to provide a large contact area. Therefore, an electrical connection having a low resistance can be achieved. Furthermore, since the third conductive layer 13 is composed of tin having a low hardness, this device is less susceptible to, for example, expansion and contraction of the insulating material caused by vibration or temperature change. As a result, a semiconductor chip having high connection reliability can be inexpensively provided.

In addition, since the second conductive layer 12 is composed of copper, the third conductive layer 13 composed of tin can be formed by electroless plating. Therefore, a semiconductor chip having high connection reliability can be inexpensively provided.

### Second Embodiment

FIG. 5 is a schematic cross-sectional view showing the state before mounting a semiconductor chip 2 on a wiring substrate 4 in a semiconductor device according to a second embodiment of the present invention. In the semiconductor device shown in FIG. 5, a first conductive layer 11 is disposed in an opening 9a of a passivation film 9 and is not in contact with the surface of the passivation film 9 except for the side faces of the opening 9a. Other parts are the same as those of the semiconductor device of the first embodiment shown in FIG. 2. The same parts as those in the first embodiment have the same reference numerals. The steps of producing the semiconductor device are almost the same as the steps of the first embodiment shown in FIGS. 3A to 3D and FIGS. 4E to 4G.

According to the second embodiment, in a bump 10 including the first conductive layer 11, a second conductive layer 12, and a third conductive layer 13, the first conductive layer 11 is disposed only in the area of the opening 9a of the passivation film 9 and is not in contact with the surface of the passivation film 9. As shown in FIG. 5, the first conductive layer 11 may be in contact with the side faces of the opening 9a of the passivation film 9. The first conductive layer 11 may have a thickness smaller than or equal to the thickness of the passivation film 9.

In the second embodiment, the first conductive layer 11 is disposed so as not to be in contact with the surface of the passivation film 9 except for the side faces of the opening 9a. Therefore, only the second conductive layer 12 and the third conductive layer 13 are disposed on the surface of the passivation film 9. Accordingly, when the semiconductor chip 2 is mounted by pressurizing, the stress applied on the passivation film 9 can be relieved by the flexibility of the second conductive layer 12 and the third conductive layer 13. As a result, the generation of damage such as cracks on the passivation film 9 can be prevented. Thus, a semiconductor chip having high connection reliability can be achieved.

### Third Embodiment

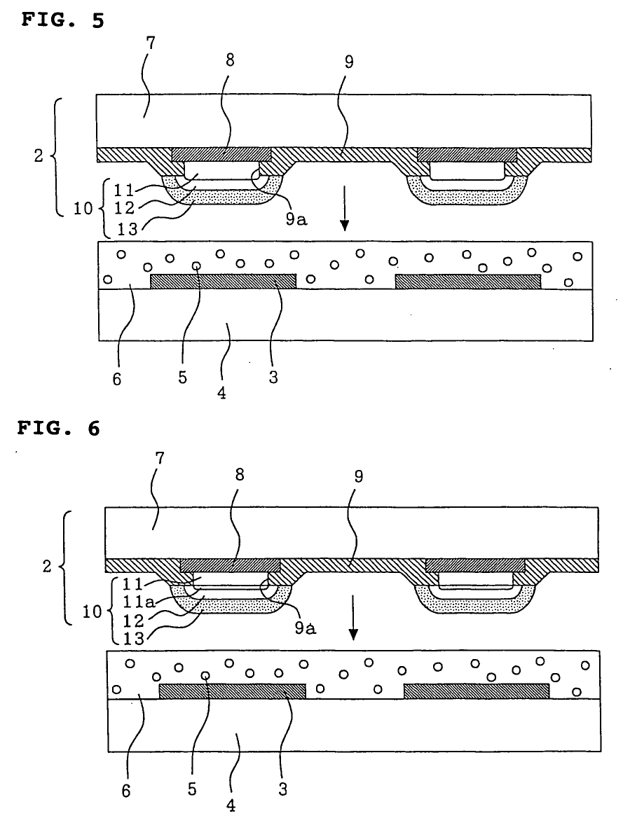

FIG. 6 is a schematic cross-sectional view showing the state before mounting a semiconductor chip 2 on a wiring substrate 4 in a semiconductor device according to a third embodiment of the present invention. In the semiconductor device in FIG. 6, as in the semiconductor device according to the second embodiment, a first conductive layer 11 is disposed in the opening 9a of the passivation film 9 and is not in contact with the surface of the passivation film 9 except for the side faces of the opening 9a. In the semiconductor device shown in FIG. 6, a part of the first conductive layer 11 adjacent to the second conductive layer 12 forms an auxiliary conductive layer 11a. The auxiliary conductive layer 11a is composed of gold, which has a hardness lower than the remaining part of the first conductive layer 11 (composed of nickel) other than the auxiliary conductive layer 11a. Although the auxiliary conductive layer 11a is composed of gold in the third embodiment, the auxiliary conductive layer 11a may be composed of another metal or the like having a hardness lower than nickel. For example, the auxiliary conductive layer 11a can be formed by plating as follows: Firstly, the remaining part of the first conductive layer 11 other than the auxiliary conductive layer 11a is formed. Subsequently, a gold layer having a thickness of 0.1 to 3.0 μm is formed by immersion plating (see FIG. 3B). The auxiliary conductive layer 11a preferably has a thickness of 0.2 to 1.0 μm. In order to form the auxiliary conductive layer 11a having a large thickness, after the immersion plating, a chemical reduction plating is performed.

Other parts are the same as those of the semiconductor device of the second embodiment shown in FIG. 5. The same parts as those in the second embodiment have the same reference numerals.

In the third embodiment, the auxiliary conductive layer 11a is disposed so as not to be in contact with the surface of the passivation film 9 except for the side faces of the opening 9a. Alternatively, the auxiliary conductive layer 11a composed of gold may be formed so as to be in contact with the surface of the passivation film 9 because gold has a low hardness and cracks are not generated on the passivation film 9.

In the third embodiment, an external connection electrode 8 is formed so as to have a thickness of at least 0.2 μm. When the external connection electrode 8 has a thickness of at least 0.2 μm, the generation of cracks on a substrate 7 (composed of silicon) of the semiconductor chip 2 can be prevented, for example, in the step of bonding the semiconductor chip 2 on the wiring substrate 4.

In the semiconductor devices according to the first embodiment and the second embodiment, the same advantage can be achieved by controlling the thickness of the external connection electrode 8 to be at least 0.2 μm.

In the third embodiment, a part of the first conductive layer 11 adjacent to the second conductive layer 12 forms the auxiliary conductive layer 11a composed of gold having a low hardness. This structure can effectively prevent the generation of cracks on the substrate 7 of the semiconductor chip 2.

Furthermore, the external connection electrode 8 composed of a metal such as aluminum has a thickness of at least 0.2 μm. This structure can more effectively prevent the generation of cracks on the substrate 7 of the semiconductor chip 2, for example, in the step of bonding the semiconductor chip 2 on the wiring substrate 4.

### Fourth Embodiment

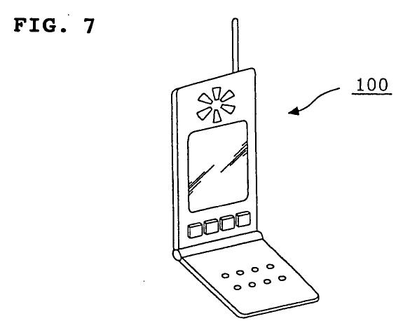

FIG. 7 is a schematic perspective view showing an example of electronic equipment according to a fourth embodiment of the present invention. Electronic equipment 100 in FIG. 7 is a cellular phone, which includes the semiconductor device described in the first embodiment, the second embodiment, or the third embodiment of the present invention.

In addition to the cellular phone shown in FIG. 7, the semiconductor device according to the first embodiment, the second embodiment, or the third embodiment of the present invention can be used in various types of electrical equipment such as a notebook-size personal computer, an electronic notebook, an electronic desk calculator, a liquid crystal projector, and a printer.

1. A semiconductor device comprising:
a semiconductor chip including a bump;
a wiring substrate including a land; and
conductive particles for connecting the bump with the land, the conductive particles being dispersed in an insulating material,
wherein the bump includes a first conductive layer, a second conductive layer that is in contact with the first conductive layer, and a third conductive layer that is in contact with the second conductive layer, and wherein the conductive particles are inserted in the third conductive layer to establish the electrical connection.

2. The semiconductor device according to claim 1, wherein the thickness of the third conductive layer is controlled so that the conductive particles can protrude from the insulating material into the third layer, with at least one-fourth of the diameter of the conductive particles being inserted in the third conductive layer.

3. The semiconductor device according to claim 1, wherein the bump is directly in contact with the land, and wherein the thickness of the third conductive layer is controlled so that the conductive particles can protrude from the insulating material into the third layer,with at least one-half of the diameter of the conductive particles being inserted in the third conductive layer.

4. The semiconductor device according to claim 3, further comprising:
a catalyst disposed between the first conductive layer and the second conductive layer and/or between the second conductive layer and the third conductive layer.

5. The semiconductor device according to claim 4, further comprising:
a passivation film having an opening on an external connection electrode, wherein the first conductive layer is disposed in the opening so as not to be in contact with the surface of the passivation film except for the side faces of the opening.

6. The semiconductor device according to claim 5, wherein the conductive particles have a hardness higher than the hardness of the third conductive layer.

7. The semiconductor device according to claim 6, wherein the conductive particles comprise nickel.

8. The semiconductor device according to claim 7, wherein a part of the first conductive layer adjacent to the second conductive layer forms an auxiliary conductive layer, and the auxiliary conductive layer has a hardness lower than the hardness of the remaining part of the first conductive layer other than the auxiliary conductive layer.

9. The semiconductor device according to claim 8, wherein the auxiliary conductive layer comprises gold.

10. A semiconductor chip comprising:
a substrate;
an external connection electrode disposed on the substrate;
a bump comprising a first conductive layer, a second conductive layer disposed on the first conductive layer, and a third conductive layer disposed on the second conductive layer, the bump being electrically connected with the external connection electrode; and
a passivation film having an opening on the external connection electrode,
wherein the first conductive layer is in contact with the upper surface of the external connection electrode in the inner surface of the opening of the passivation film and is not in contact with the surface of the passivation film except for the side faces of the opening.

11. The semiconductor chip according to claim 10, wherein the third conductive layer comprises tin.

12. The semiconductor chip according to claim 11, wherein the second conductive layer comprises copper.

13. The semiconductor chip according to claim 12, wherein the external connection electrode has a thickness of at least 0.2 μm.

14. The semiconductor chip according to claim 13, wherein a part of the first conductive layer adjacent to the second conductive layer forms an auxiliary conductive layer, and the auxiliary conductive layer has a hardness lower than the hardness of the remaining part of the first conductive layer other than the auxiliary conductive layer.

15. The semiconductor chip according to claim 14, wherein the auxiliary conductive layer comprises gold.

16. A method for producing a semiconductor device to connect a semiconductor chip having a bump with a wiring substrate having a land, the method comprising the steps of:
forming a first conductive layer of the bump;
forming a second conductive layer of the bump so as to be in contact with the first conductive layer;
forming a third conductive layer of the bump so as to be in contact with the second conductive layer;
disposing an insulating material in which conductive particles are dispersed on the wiring substrate or the semiconductor chip;
pressing the bump or the land toward the insulating material to insert the conductive particles in the third conductive layer, thereby electrically connecting the bump with the land.

17. The method for producing a semiconductor device according to claim 16, further comprising the step of:
providing a catalyst between the first conductive layer and the second conductive layer and/or between the second conductive layer and the third conductive layer.

18. The method for producing a semiconductor device according to claim 17, wherein at least one of the first conductive layer, the second conductive layer, and the third conductive layer is formed by electroless plating.

19. The method for producing a semiconductor device according to claim 18, further comprising the step of:
forming an auxiliary conductive layer as a part of the first conductive layer adjacent to the second conductive layer, wherein the auxiliary conductive layer has a hardness lower than the hardness of the remaining part of the first conductive layer other than the auxiliary conductive layer.

20. Electronic equipment comprising the semiconductor device according to claim 1.
